(19) United States
(12) Patent Application Publication
(10) Pub. No.: US 2025/0214340 A1
(43) Pub. Date: Jul. 3, 2025

(54) INKJET PRINTER DEVICE AND MANUFACTURING METHOD OF INKJET PRINTER HEAD

(71) Applicant: Samsung Display Co., Ltd., Yongin-si (KR)

(72) Inventors: JUNGHAN SEO, Yongin-si (KR); JAESIK KIM, Yongin-si (KR); WOO YONG SUNG, Yongin-si (KR); KWANHYUCK YOON, Yongin-si (KR); SEUNGHO YOON, Yongin-si (KR); BYEONGJUN LEE, Yongin-si (KR); HYEMIN LEE, Yongin-si (KR); SEUNGGUN CHAE, Yongin-si (KR)

(73) Assignee: Samsung Display Co., Ltd., Yongin-si (KR)

(21) Appl. No.: 18/948,899

(22) Filed: Nov. 15, 2024

(30) Foreign Application Priority Data
Jan. 2, 2024 (KR) 10-2024-0000509

(51) Int. Cl. B41J 2/16; B41J 2/14; C07F 7/08; C07F 7/12; C07F 7/18

(52) U.S. Cl. CPC B41J 2/1606; B41J 2/14201; B41J 2/1433; B41J 2/164; C07F 7/0836; C07F 7/12; C07F 7/1804; B41J 2002/14475

(57) ABSTRACT

An inkjet printer device includes a stage, and an inkjet printer head disposed on the stage. The inkjet printer head includes a chamber part for providing ink, and a nozzle part which is disposed under the chamber part and in which a plurality of outlet ports for discharging the ink are defined, the nozzle part includes a first inorganic layer, a metal oxide layer disposed on a first upper surface of the first inorganic layer, a second inorganic layer disposed on a first lower surface of the first inorganic layer, and a self-assembled monolayer disposed on a lower surface of the second inorganic layer, a contact angle of the first lower surface with respect to water is lower than a contact angle of the first upper surface with respect to water, and the first inorganic layer and the second inorganic layer include a same material.

### CROSS-REFERENCE TO RELATED APPLICATIONS

This application claims priority to and benefits of Korean Patent Application No. 10-2024-0000509 under 35 U.S.C. § 119, filed on Jan. 2, 2024, in the Korean Intellectual Property Office (KIPO), the entire contents of which are incorporated herein by reference.

### BACKGROUND

### 1. Technical Field

The disclosure relates to an inkjet printer device and a manufacturing method of an inkjet printer head for improving the precision of ink discharge.

### 2. Description of the Related Art

With the development of multimedia, the importance of display devices has increased. In response, various types of display devices such as an organic light emitting display (OLED), a liquid crystal display (LCD), and the like are used.

A device for displaying an image of a display device includes a display panel such as an organic light emitting display panel or a liquid crystal display panel. Among them, a light emitting display panel may include light emitting elements, and examples of a light emitting diode (LED) may include an organic light emitting diode (OLED) that use an organic substance as a light emitting material, an inorganic light emitting diode that use an inorganic substance as a light emitting material, and the like. An inkjet printer device may be used to align light emitting elements included in a display device. An ink or a solution may be printed using an inkjet, and subjected to a post-treatment process to transfer an inorganic light emitting element or form an organic material layer. In an inkjet printer device, an ink or a solution may be supplied to an inkjet head, and the inkjet head may perform a process of spraying the ink or solution onto a substrate to be processed (e.g., a target substrate).

### SUMMARY

The disclosure provides an inkjet printer device with excellent ink discharge efficiency and wear resistance properties.

The disclosure also provides a method of manufacturing an inkjet printer head for providing an inkjet printer head with excellent ink discharge efficiency.

According to an embodiment of the disclosure, an inkjet printer device may include a stage, and an inkjet printer head disposed on the stage. The inkjet printer head may include a chamber part for providing ink, and a nozzle part which is disposed under the chamber part and in which a plurality of outlet ports for discharging the ink are defined, the nozzle part may include a first inorganic layer, a metal oxide layer disposed on a first upper surface of the first inorganic layer, a second inorganic layer disposed on a first lower surface of the first inorganic layer, and a self-assembled monolayer disposed on a lower surface of the second inorganic layer, a contact angle of the first lower surface with respect to water may be lower than a contact angle of the first upper surface with respect to water, and the first inorganic layer and the second inorganic layer may include a same material.

In an embodiment, a surface roughness of the first lower surface may be higher than a surface roughness of the first upper surface.

In an embodiment, the contact angle of the first lower surface with respect to water may be lower than a contact angle of the lower surface of the second inorganic layer with respect to water.

In an embodiment, a thickness of the second inorganic layer may be in a range of about 1 nm to about 50 nm, and a thickness of the first inorganic layer may be less than the thickness of the second inorganic layer.

In an embodiment, the metal oxide layer may include aluminum oxide, and the first inorganic layer and the second inorganic layer may each include a silicon oxide.

In an embodiment, an atomic ratio of oxygen (O) atom included in the first lower surface may be higher than an atomic ratio of oxygen (O) atom included in the first upper surface.

In an embodiment, the second inorganic layer and the self-assembled monolayer may not overlap the plurality of outlet ports defined in the nozzle part in a plan view.

In an embodiment, a contact angle of a lower surface of the self-assembled monolayer with respect to water may be in a range of about 90° to about 180°.

In an embodiment, the self-assembled monolayer may include a hydrocarbon portion, a head portion connected to an end of the hydrocarbon portion, and a terminal portion connected to another end of the hydrocarbon portion, and the head portion may be in contact with the lower surface of the second inorganic layer.

In an embodiment, the head portion may include one of moieties represented by Formula 1-1, Formula 1-2, and Formula 1-3.

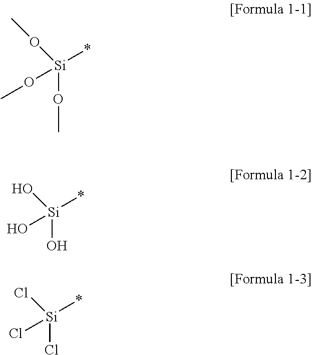

In Formula 1-1 to Formula 1-3, [symbol] may be a position connected to the end of the hydrocarbon portion.

In an embodiment, the terminal portion may include one of moieties represented by Formula 2-1, Formula 2-2, Formula 2-3, and Formula 2-4.

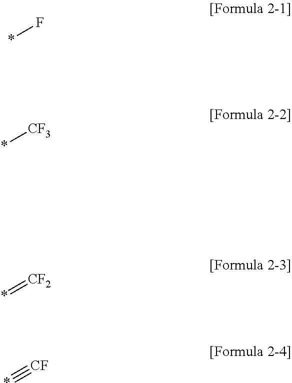

In Formula 2-1 to Formula 2-4, [symbol] may be a position connected to the another end of the hydrocarbon portion.

In an embodiment, the hydrocarbon portion may be an unsubstituted alkyl group having 8 to 60 carbon atoms.

In an embodiment, the inkjet printer head may further include a piezoelectric element part disposed between the chamber part and the nozzle part and applying pressure to the ink.

In an embodiment, the nozzle part may further include an organic layer disposed between the piezoelectric element part and the first inorganic layer.

In an embodiment, the organic layer may include polyimide (PI).

In an embodiment of the disclosure, a method for manufacturing an inkjet printer head including a chamber part for providing ink, a piezoelectric element part disposed under the chamber part and applying pressure to the ink, and a nozzle part disposed under the piezoelectric element part and having a plurality of outlet ports, may include forming the nozzle part. The forming of the nozzle part may include providing a preliminary nozzle part including a metal oxide layer, a preliminary first inorganic layer disposed on a lower surface of the metal oxide layer, and a preliminary self-assembled layer disposed on a lower surface of the preliminary first inorganic layer, forming a first inorganic layer by irradiating the preliminary self-assembled layer with plasma to remove the preliminary self-assembled layer from the lower surface of the preliminary first inorganic layer, forming a second inorganic layer on a lower surface of the first inorganic layer, and forming a self-assembled monolayer on a lower surface of the second inorganic layer.

In an embodiment, in the forming of the first inorganic layer, the plasma may be irradiated from the lower surface of the preliminary self-assembled layer, and the plasma may be irradiated onto at least a portion of the lower surface of the preliminary first inorganic layer.

In an embodiment, the forming of the second inorganic layer may be performed by a thermal deposition process or an electron beam deposition process.

In an embodiment, the preliminary first inorganic layer, the first inorganic layer, and the second inorganic layer may each include a silicon oxide.

In an embodiment, the preliminary self-assembled layer and the self-assembled monolayer may include a same material.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1A is a perspective view of an inkjet printer device according to an embodiment of the disclosure;

FIG. 1B is a perspective view schematically showing some components of an inkjet printer device according to an embodiment of the disclosure;

FIG. 2 is a schematic cross-sectional view of an enlarged portion of an inkjet printer head according to an embodiment of the disclosure;

FIG. 3A and FIG. 3B are each a schematic cross-sectional view showing some components of an inkjet printer head according to an embodiment of the disclosure;

FIG. 4 is a flowchart showing some of the steps of a manufacturing method of an inkjet printer head according to an embodiment of the disclosure; and

FIG. 5A to FIG. 5D are schematic cross-sectional views sequentially showing some of the steps of a manufacturing method of an inkjet printer head according to an embodiment of the disclosure.

### DETAILED DESCRIPTION OF THE EMBODIMENTS

The disclosure may be modified in many alternate forms, and thus embodiments will be illustrated in the drawings and described in detail. It should be understood, however, that it is not intended to limit the disclosure to the particular forms disclosed, but rather, is intended to cover all modifications, equivalents, and alternatives falling within the spirit and scope of the disclosure.

Like reference numerals are used to refer to like elements in describing each drawing. In the accompanying drawings, the dimensions of elements are exaggerated for clarity of the disclosure. It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the disclosure. The terms of a singular form may include plural forms unless the context clearly indicates otherwise.

In the application, it should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The terms “film” and “thin film” are used herein for simplicity. The “film” and “thin film” are intended to mean any continuous or discontinuous structures and materials deposited by methods disclosed herein. For example, “film” and “thin film” may include 2D materials, nanorods, nanotubes, or nanoparticles, or single, partial or complete molecular layers, or partial or complete atomic layers, or clusters of atoms and/or molecules. The “film” and “thin film” may include a material or layer with pinholes, but may still be at least partially continuous.

In the specification, “substituted or unsubstituted” may mean being substituted or unsubstituted with one or more substituents selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a hetero ring group. In addition, each of the substituents illustrated above may be substituted or unsubstituted. For example, a biphenyl group may be interpreted as an aryl group, and may be interpreted as a phenyl group substituted with a phenyl group.

In the specification, the alkyl group may be linear, branched or cyclic. The number of carbon atoms in the alkyl group may be in a range of 1 to 60. For example, the number of carbon atoms in the alkyl group may be in a range of 1 to 30. For example, the number of carbon atoms in the alkyl group may be in a range of 1 to 20. For example, the number of carbon atoms in the alkyl group may be in a range of 1 to 10. For example, the number of carbon atoms in the alkyl group may be in a range of 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantly group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, and an n-triacontyl group, and the like, but the disclosure is not limited thereto.

In the specification the cycloalkyl group may be a ring-type alkyl group. The number of carbon atoms in the cycloalkyl group may be in a range of 3 to 50. For example, the number of carbon atoms in the cycloalkyl group may be in a range of 3 to 30. For example, the number of carbon atoms in the cycloalkyl group may be in a range of 3 to 20. For example, the number of carbon atoms in the cycloalkyl group may be in a range of 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and the like, but the disclosure is not limited thereto.

In the specification, the alkenyl group may be a hydrocarbon group including one or more carbon double bonds in the middle or at a terminal of an alkyl group having 2 or more carbon atoms. The alkenyl group may be linear or branched. The number of carbon atoms in the alkenyl group may be in a range of 2 to 30. For example, the number of carbon atoms in the alkenyl group may be in a range of 2 to 20. For example, the number of carbon atoms in the alkenyl group may be in a range of 2 to 10. However, the disclosure is not limited thereto. Examples of the alkenyl group may include a vinyl group, a 1-butenyl group, a 1-pentenyl group, a 1,3-butadienyl aryl group, a styrenyl group, a styrylvinyl group, and the like, but the disclosure is not limited thereto.

In the specification, the aryl group may be a functional group or substituent derived from an aromatic hydrocarbon ring. The aryl group may be a monocyclic aryl group or a polycyclic aryl group. The number of ring-forming carbon atoms in the aryl group may be in a range of 6 to 60. For example, the number of ring-forming carbon atoms in the aryl group may be in a range of 6 to 30. For example, the number of ring-forming carbon atoms in the aryl group may be in a range of 6 to 20. For example, the number of ring-forming carbon atoms in the aryl group may be in a range of 6 to 15. Examples of the aryl group may include a phenyl group, a naphthyl group, a fluorenyl group, an anthracene group, a phenanthrene group, a biphenyl group, a terphenyl group, a quarterphenyl group, a quinquephenyl group, a sexiphenyl group, a triphenylenyl group, a pyrenyl group, a benzofluoranthene group, a chrysene group, and the like, but the disclosure is not limited thereto.

In the specification, a fluorenyl group may be substituted, and two substituents may be bonded to each other to form a spiro structure. Examples in which a fluorenyl group is substituted are as follows. However, the disclosure is not limited thereto.

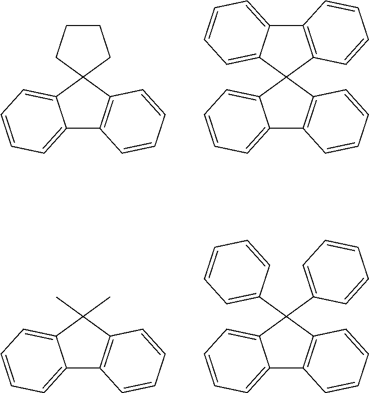

In the specification, a heterocyclic group may be a functional group or substituent derived from a ring including one or more of B, O, N, P, Si, and S as a hetero atom. The heterocyclic group may include an aliphatic heterocyclic group and an aromatic heterocyclic group. The aromatic heterocyclic group may be a heteroaryl group. The aliphatic heterocyclic group and the aromatic heterocyclic group may be monocyclic or polycyclic.

In the specification, the heteroaryl group may include one or more of B, O, N, P, Si, and S as a hetero atom. In case that the heteroaryl group includes two or more hetero atoms, the two or more hetero atoms may be the same or different from each other. The heteroaryl group may be a monocyclic hetero ring group or a polycyclic hetero ring group. The number of ring-forming carbon atoms in the heteroaryl group may be in a range of 2 to 30. For example, the number of ring-forming carbon atoms in the heteroaryl group may be in a range of 2 to 20. For example, the number of ring-forming carbon atoms in the heteroaryl group may be in a range of 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazinyl group, a pyrazinyl group, a quinoline group, a quinazoline group, a quinoxaline group, a phenothiazine group, a phthalazine group, a pyrido pyrimidine group, a pyrido pyrazine group, a pyrazino pyrazine group, an isoquinoline group, an indole group, a carbazole group, an N-arylcarbazol group, an N-heteroarylcarbazole group, an N-alkylcarbazol group, a benzooxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilol group, a dibenzofuran group, and the like, but the disclosure is not limited thereto.

In the specification, the above-described description of an aryl group may be applied to an arylene group except that the arylene group is a divalent group. The above-described description of a heteroaryl group may be applied to a heteroarylene group except that the heteroarylene group is a divalent group.

In the specification, the silyl group may include an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and the like, but the disclosure is not limited thereto.

In the specification, the thio group may include an alkyl thio group and an aryl thio group. The thio group may include a sulfur atom that is bonded to the alkyl group or the aryl group defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and the like, but the disclosure is not limited thereto.

In the specification, the oxy group may include an oxygen atom that is bonded to the alkyl group or the aryl group defined above. The oxy group may include an alkoxy group and an aryl oxy group. In the specification, the alkoxy group may be linear, branched or cyclic. The number of carbon atoms in the alkoxy group may be in a range of 1 to 20. For example, the number of carbon atoms in the alkoxy group may be in a range of 1 to 10. However, the disclosure is not limited thereto. Examples of the oxy group may include methoxy, ethoxy, n-propoxy, isopropoxy, butoxy, pentyloxy, hexyloxy, octyloxy, nonyloxy, decyloxy, benzyloxy, and the like, but the disclosure is not limited thereto.

In the specification, the boron group may include a boron atom that is bonded to the alkyl group or the aryl group defined above. The boron group may include an alkyl boron group and an aryl boron group. Examples of the boron group may include a dimethylboron group, a diethylboron group, a t-butylmethylboron group, a diphenylboron group, a phenylboron group, and the like, but the disclosure is not limited thereto.

Hereinafter, an inkjet printer head and an inkjet printer device according to an embodiment will be described with reference to the drawings.

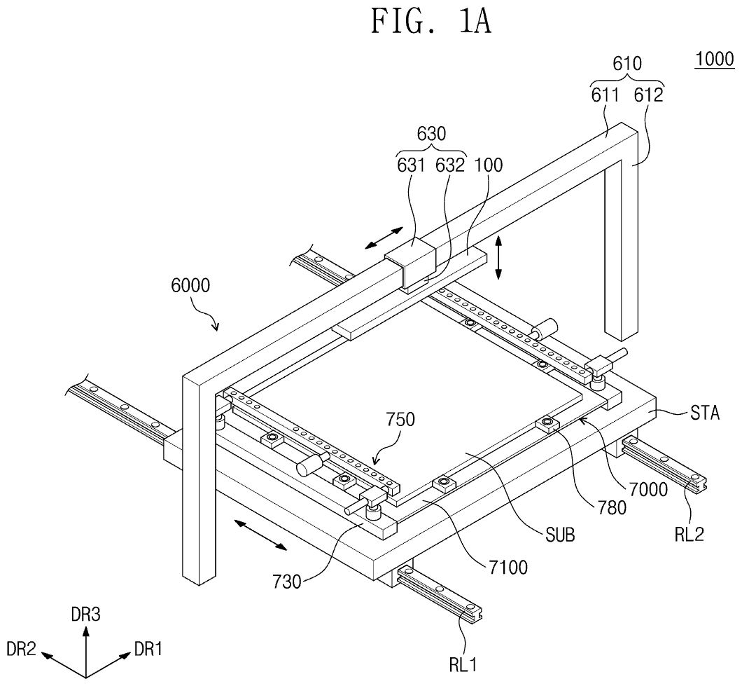

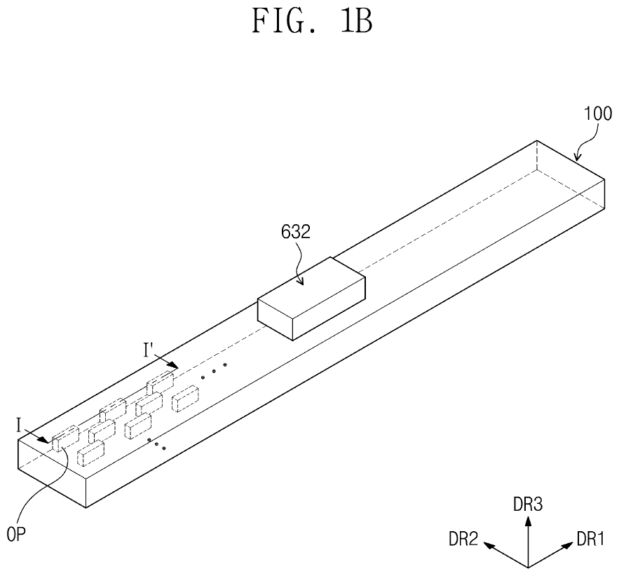

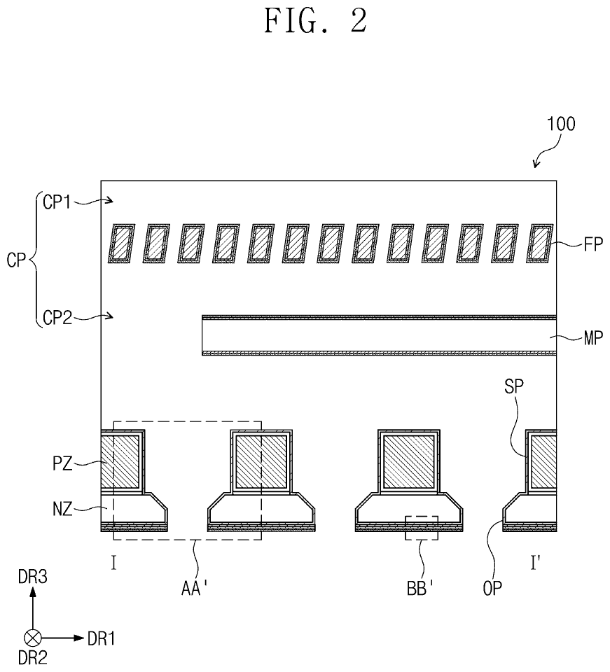

FIG. 1A is a schematic perspective view of an inkjet printer device according to an embodiment. FIG. 1B is a schematic perspective view showing some components of an inkjet printer device of an embodiment. FIG. 2 is a schematic cross-sectional view of an inkjet printer head according to an embodiment. FIG. 2 schematically illustrates a cross-section corresponding to line I-I′ of FIG. 1B.

Referring to FIG. 1A and FIG. 1B, an inkjet printer device 1000 may include an inkjet printer head 100 which includes multiple nozzle parts NZ (see FIG. 2) and a probe device 7000. The inkjet printer device 1000 may further include a first moving unit including first and second rails RL1 and RL2 for moving a stage STA, a base frame 6000, and the stage STA. The inkjet printer device 1000 according to an embodiment may spray an ink onto a target substrate SUB and align particles dispersed in the ink, e.g., particles such as bipolar elements, on the target substrate SUB. For example, the particles dispersed in the ink may be sprayed onto the target substrate SUB through the inkjet printer head 100. On the target substrate SUB onto which the ink is sprayed, an electric field may be formed by the probe device 7000, and the particles included in the ink may be aligned on the target substrate SUB. While a printing process is not performed, ink supplied to the inkjet printer head 100 may not flow in the inkjet printer head 100, and particles dispersed in the ink may precipitate in the inkjet printer head 100.

A first direction DR1, a second direction DR2, and a third direction DR3 are defined in drawings describing the inkjet printer device 1000. The first direction DR1 and the second direction DR2 may be directions perpendicular to each other on a plane. The third direction DR3 may be a direction perpendicular to the plane on which the first direction DR1 and the second direction DR2 are positioned.

Hereinafter, in embodiments describing the inkjet printer device 1000, unless otherwise stated, “upper portion” may be a side of the third direction DR3, and “upper surface” may be a surface facing the side of the third direction DR3. In addition, “lower portion” may be another side of the third direction DR3, and “lower surface” may be a surface facing the another side of the third direction DR3. In addition, “left,” “right,” “upper,” and “lower” may be directions in which the inkjet printer device 1000 is viewed from above. For example, “right side” may be a side of the first direction DR1, “left side” may be another side of the first direction DR1, “upper side” may be a side of the second direction DR2, and “lower side” may be another side of the second direction DR2.

The target substrate SUB may be provided on the probe device 7000, and the probe device 7000 may form an electric field in an upper portion of the target substrate SUB, wherein particles included in ink may be aligned such that an end portion of the particles faces in a direction by the electric field.

A sub-stage 7100 may provide a space in which the target substrate SUB is disposed. A probe support 730, a probe unit 750, and an aligner 780 may be disposed on the sub-stage 7100. The overall planar shape of the sub-stage 7100 may follow a planar shape of the target substrate SUB. For example, if the target substrate SUB has a rectangular shape, the overall shape of the sub-stage 7100 may be rectangular in a plan view.

At least one aligner 780 may be disposed on the sub-stage 7100. The aligner 780 may be disposed on each side of the sub-stage 7100, and a region surrounded by multiple aligners 780 may be a region in which the target substrate SUB is disposed.

The probe support 730 and probe unit 750 may be disposed on the sub-stage 7100. The probe support 730 may provide a space in which the probe unit 750 is disposed on the sub-stage 7100.

The probe unit 750 may be disposed on the probe support 730 and form an electric field on the target substrate SUB prepared on the sub-stage 7100.

The stage STA may provide a region in which the probe device 7000 is disposed. The first moving unit may adjust the relative position between the stage STA and the inkjet printer head 100. The first moving unit may include the first and second rails RL1 and RL2.

The stage STA may be disposed on the first and second rails RL1 and RL2 extending in the second direction DR2. The stage STA may be disposed on the first and second rails RL1 and RL2 and reciprocate in the second direction DR2 to allow a printing process to be performed on the entire region of the target substrate SUB.

The target substrate SUB described in the specification may be an object to be processed by the inkjet printer device 1000 according to an embodiment, and as the target substrate SUB may be applied to an inorganic light emitting display device including an inorganic light emitting diode which includes an inorganic semiconductor, an organic light emitting display device including an organic light emitting diode which includes an organic light emitting layer, a micro-light emitting diode display device including a micro-LED, a quantum dot light emitting display device using a quantum dot light emitting diode which includes a quantum dot light emitting layer, or the like.

The inkjet printer head 100 may serve to print ink on the target substrate SUB. The inkjet printer head 100 may spray an ink onto the target substrate SUB during the inkjet printer device 1000 is operated. The inkjet printer head 100 may spray ink supplied from an ink provider onto the target substrate SUB provided on the sub-stage 7100.

The ink sprayed from the inkjet printer head 100 may be in a solution state or in a colloid state. The ink may include a solvent and multiple particles dispersed in the solvent.

The solvent may be, but is not limited to, acetone, water, alcohol, toluene, propylene glycol (PG) methyl acetate, propylene glycol methyl acetate (PGMA), triethylene glycolmonobutyl ether (TGBE), diethylene glycol monophenyl ether (DGPE), an amide-based solvent, a dicarbonyl-based solvent, diethylene glycol dibenzoate, a tricarbonyl-based solvent, triethyl citrate, a phthalate-based solvent, benzyl butylphthalate, bis(2-ethylhexyl) phthalate, bis(2-ethylhexyl) isophthalate, ethyl phthalyl ethyl glycolate, or the like.

The particles may be included in a state of being dispersed in the solvent and provided to the inkjet printer head 100 through the ink provider, and may be sprayed through the inkjet printer head 100. For example, the particles included in the ink may include a quantum dot light emitting element. However, the disclosure is not limited thereto.

The inkjet printer head 100 may be disposed above the probe device 7000 or the stage STA. The inkjet printer head 100 may be mounted on and movable along the base frame 6000. The base frame 6000 may include a first support 610 and a second moving unit 630. The inkjet printer head 100 may be mounted on the second moving unit 630 disposed on the first support 610. A method by which the inkjet printer head 100 is mounted on the second moving unit 630 is not particularly limited. For example, the inkjet printer head 100 may be directly disposed on the second moving unit 630, or may be mounted on or coupled to the second moving unit 630 through a separate coupling member.

The first support 610 may include a first horizontal support 611 extending in the first direction DR1, which is a horizontal direction, and a first vertical support 612 connected to the first horizontal support 611 and extending in the third direction DR3, which is a vertical direction. The direction in which the first horizontal support 611 is extended may be the same as the first direction DR1 perpendicular to the second direction DR2, which is a direction in which the stage STA moves on the first and second rails RL1 and RL2 on a plane. The inkjet printer head 100 may be mounted on the second moving unit 630 disposed on the first horizontal support 611. The second moving unit 630 may be moved in a direction on the first horizontal support 611. The second moving unit 630 may include a moving part 631 and a fixed part 632.

The moving part 631 of the second moving unit 630 may move in the first direction DR1 on the first horizontal support 611, and the inkjet printer head 100 may be fixed to the fixed part 632 of the second moving unit 630 and move in the first direction DR1 together with the second moving unit 630. The stage STA may reciprocate in the second direction DR2 along the first and second rails RL1 and RL2, and the inkjet printer head 100 may reciprocate in the first direction DR1 with the second moving unit 630 to spray ink over the entire region of the target substrate SUB even with an inkjet printer head 100, which has a smaller area than an area of the target substrate SUB.

The stage STA may move in the second direction DR2 on the first and second rails RL1 and RL2, and the inkjet printer head 100 may move in the first direction DR1, but the disclosure is limited thereto. For example, the inkjet printer device 1000 according to an embodiment may further include a horizontal moving unit which moves the inkjet printer head 100 in the second direction DR2, and the first and second rails RL1 and RL2 that move the stage STA in the second direction DR2 may be omitted. For example, the stage STA may be fixed, and the inkjet printer head 100 may reciprocate in the first direction DR1 and the second direction DR2 on the stage STA to perform a printing process on the entire region of the target substrate SUB. For example, the relative position between the stage STA and the inkjet printer head 100 may be adjusted as the stage STA is fixed and the inkjet printer head 100 moves in the first and second directions DR1 and DR2, which are horizontal directions, or may be adjusted as the inkjet printer head 100 is fixed and the stage STA moves in the first and second directions DR1 and DR2, which are horizontal directions.

For example, the stage STA may reciprocate in the second direction DR2 using the first moving unit including the first and second rails RL1 and RL2, and the inkjet printer head 100 may reciprocate in the second direction DR2 using the second moving unit 630, but a method of adjusting the relative position of the stage STA and the inkjet printer head 100 is not limited thereto.

The inkjet printer head 100 may be mounted on the second moving unit 630 disposed on the first support 610 and be spaced apart from the stage STA by a distance in the third direction DR3. A separation distance between the inkjet printer head 100 and the stage STA in the third direction DR3 may be adjusted by the height of the first vertical support 612 of the first support 610. The separation distance between the inkjet printer head 100 and the stage STA may be adjusted within a range in which the inkjet printer head 100 has a certain interval from the target substrate SUB in case that the target substrate SUB is disposed on the stage STA, so that a space required for a printing process is secured.

On a surface of the inkjet printer head 100, e.g., a lower surface thereof, multiple outlet ports OPs may be defined. The outlet ports OPs may be spaced apart from each other. The outlet ports OPs may be disposed side by side in a direction. The outlet ports OPs may be arranged in a single row or multiple rows.

FIG. 1B schematically illustrates, but is not limited to, that the outlet ports OPs are arranged in three rows. For example, the outlet ports OPs may be disposed in a single row, or may be divided and arranged into a larger number of rows. In an embodiment, the outlet ports OP disposed in each row may be disposed in a staggered manner without overlapping each other. In an embodiment, the number of the outlet ports OPs disposed in the inkjet printer head 100 may be in a range of 128 to 1800, but the disclosure is not limited thereto. The planar shape of the outlet port OP is not particularly limited, and the outlet port OP may have, for example, a quadrangular shape in a plan view.

Referring to FIG. 1A and FIG. 2, the inkjet printer head 100 according to an embodiment may include a chamber part CP and a nozzle part NZ, and a piezoelectric element part PZ disposed between the chamber part CP and the nozzle part NZ.

The chamber part CP may be a part that receives ink from the fixed part 632 of the inkjet printer head 100 and provides the ink to the nozzle part NZ. The chamber part CP may be a part which receives ink from the fixed part 632 of the inkjet printer head 100 and transfers the ink to the nozzle part NZ, or provides ink not discharged from the nozzle part NZ back to the fixed part 632. For example, the chamber part CP may be a region disposed between the nozzle part NZ and the fixed part 632 to provide a path through which ink moves and circulate residual ink.

The chamber part CP may include a first chamber CP1, a second chamber CP2, and a filter part FP. The first and second chambers CP1 and CP2 may be parts for storing ink. The filter part FP may be disposed between the first chamber CP1 and the second chamber CP2 to distinguish the first and second chambers CP1 and CP2.

The first chamber CP1 may be disposed between the nozzle part NZ and the fixed part 632. The first chamber CP1 may allow ink supplied from an internal flow path which may be positioned inside the fixed part 632 to flow towards the filter part FP and the second chamber CP2. The ink supplied through the fixed part 632 may be introduced into the first chamber CP1. A portion of the ink introduced into the first chamber CP1 may be sprayed through the nozzle part NZ via the filter part FP and the second chamber CP2, and another portion of the ink introduced into the first chamber CP1 may be transferred to the outside of the fixed part 632 along the internal flow path of the fixed part 632. For example, the first chamber CP1 may function to transfer the ink supplied through the internal flow path of the fixed part 632 to the nozzle part NZ, or to recover ink not discharged from the nozzle part NZ back to the internal flow path of the fixed part 632.

The filter part FP may be disposed between the first chamber CP1 and the second chamber CP2. The filter part FP may allow ink supplied from the first chamber CP1 to flow into the second chamber CP2. The filter part FP may selectively pass specific particles in the ink, and may block substances (or foreign substances) other than the specific particles in the ink. The filter part FP may serve to prevent substances (or foreign substances) other than the specific particles from being introduced into the nozzle part NZ. As a result, it may be possible to prevent the nozzle part NZ from being blocked by foreign substances, or prevent foreign substances from being mixed in ink discharged through the nozzle part NZ. The filter part FP may include a metal mesh layer in which a metal forms the shape of a fibrous structure. In an embodiment, the metal which forms the metal mesh layer may be stainless steel, but the disclosure is not limited thereto.

The second chamber CP2 may be disposed between the filter part FP and the nozzle part NZ. The second chamber CP2 may allow ink supplied through the first chamber CP1 and the filter part FP to flow towards the nozzle part NZ. The ink provided through the first chamber CP1 and the filter part FP may be introduced into the second chamber CP2. A portion of the ink introduced into the second chamber CP2 may be sprayed through the nozzle part NZ. Another portion of the ink introduced into the second chamber CP2 may be transferred to the first chamber CP1 through the filter part FP. For example, the second chamber CP2 may function to transfer the ink supplied through the first chamber CP1 to the nozzle part NZ, or to recover ink not sprayed from the nozzle part NZ back to the internal flow path of the fixed part 632.

The chamber CP may further include a metal plate MP disposed between the filter part FP and the nozzle part NZ. The metal plate MP may remove impurities in ink or guide the flow of ink. The metal plate MP may generate a flow in ink remaining in the nozzle part NZ in a non-spray mode. Accordingly, the metal plate MP may prevent particles dispersed in the remaining ink from being precipitated.

The nozzle part NZ may be disposed between the chamber part CP and the target substrate SUB. The nozzle part NZ may be a portion of the inkjet printer head 100 that is the most adjacent to the target substrate SUB. Multiple outlet ports OPs through which ink is discharged may be defined in the nozzle part NZ. The nozzle part NZ may allow ink supplied from the chamber part CP to flow to the outside of the inkjet printer head 100. For example, the ink provided from the chamber part CP may be sprayed to the outside of the inkjet printer head 100 through the outlet port OP of the nozzle part NZ. Ink discharged through the outlet port OP may be sprayed onto the target substrate SUB.

The piezoelectric element part PZ may be disposed between the chamber part CP and the nozzle part NZ. The piezoelectric element part PZ may have multiple storage parts SPs defined on the piezoelectric element part PZ. The storage parts SP may correspond to the outlet ports OP defined in the nozzle part NZ. The storage part SP may be a place in which the ink supplied from the chamber part CP is temporarily stored before being discharged from the outlet port OP. A voltage applied to the piezoelectric element part PZ may control the pressure applied to the ink temporarily stored in the storage part SP. In case that a certain voltage is applied to the piezoelectric element part PZ, the ink temporarily stored in the storage part SP may be subjected to a pressure. If a pressure greater than a specific numerical value is applied to the ink temporarily stored in the storage part SP, the ink may be sprayed onto the target substrate through the storage part SP and the outlet port OP. For example, whether the ink temporarily stored in the storage part SP is discharged from the outlet port OP or the amount of the ink temporarily stored in the storage part SP discharged from the outlet port OP may be controlled according to the voltage applied to the piezoelectric element part PZ.

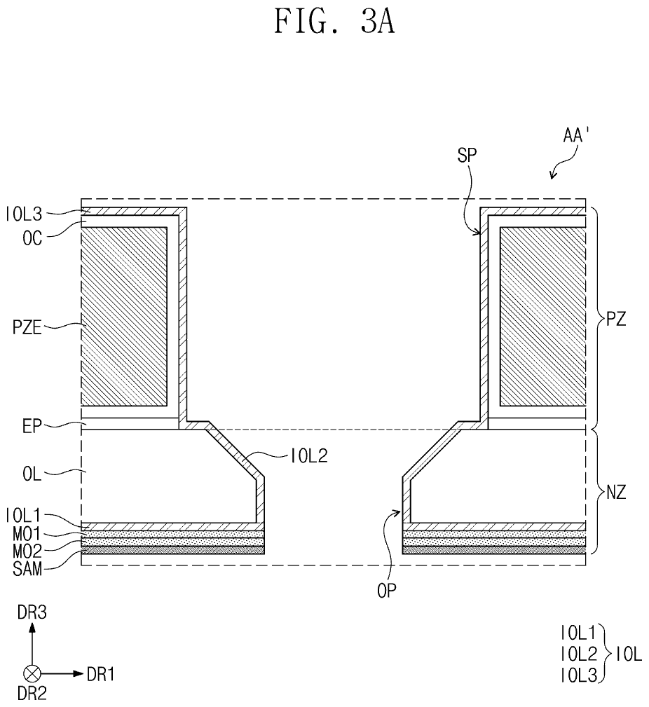

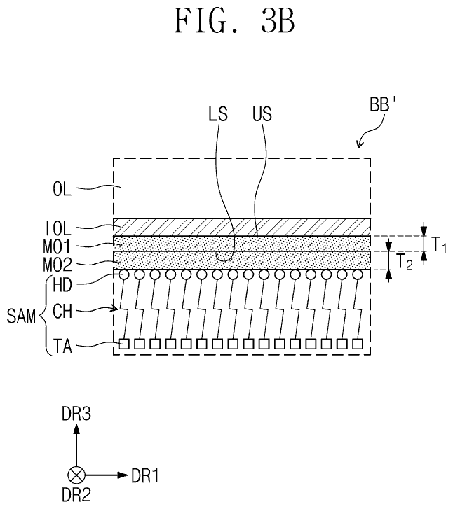

FIG. 3A and FIG. 3B are each a schematic cross-sectional view showing some components of an inkjet printer head according to an embodiment of the disclosure in detail. FIG. 3A is a schematic cross-sectional view illustrating an enlarged region corresponding to AA′ illustrated in FIG. 2. FIG. 3B is a schematic cross-sectional view illustrating an enlarged region corresponding to BB′ illustrated in FIG. 2.

Referring to FIG. 3A and FIG. 3B, the nozzle part NZ according to an embodiment may include a first inorganic layer MO1, a second inorganic layer MO2 disposed under the first inorganic layer MO1, a self-assembled monolayer SAM disposed under the second inorganic layer MO2, and a metal oxide layer IOL disposed on the first inorganic layer MO1. Each of the first inorganic layer MO1, the second inorganic layer MO2, and the self-assembled monolayer SAM may not overlap the outlet port OP defined in the nozzle part NZ in a plan view.

The second inorganic layer MO2 may be disposed on a first lower surface LS of the first inorganic layer MO1. The first inorganic layer MO1 and the second inorganic layer MO2 may include a same material. The first inorganic layer MO1 and the second inorganic layer MO2 may each include a silicon oxide. The first inorganic layer MO1 and the second inorganic layer MO2 may each include SiO₂. The first inorganic layer MO1 and the second inorganic layer MO2 may each be formed at different times from a same material through a same process. The first inorganic layer MO1 and the second inorganic layer MO2 may be deposited in the form of a thin film at different times by a thermal evaporation method or an electron beam evaporation method.

The first inorganic layer MO1 and the second inorganic layer MO2 may have different thicknesses. For example, a thickness T1 of the first inorganic layer MO1 may be less than a thickness T2 of the second inorganic layer MO2. The thickness T2 of the second inorganic layer MO2 may be in a range of about 1 nm to about 50 nm, and the thickness T1 of the first inorganic layer MO1 may less than the thickness T2 of the second inorganic layer MO2 specified within the aforementioned numerical range. For example, the thickness T2 of the second inorganic layer MO2 may be about 10 nm, and the thickness T1 of the first inorganic layer MO1 may be in a range of about 5 nm to about 9 nm. However, the disclosure is not limited thereto, and the thickness T2 of the second inorganic layer MO2 and the thickness T1 of the first inorganic layer MO1 may have various values.

The self-assembled monolayer SAM may be disposed under the second inorganic layer MO2. The self-assembled monolayer SAM may be disposed on a lower surface of the second inorganic layer MO2. A lower surface of the self-assembled monolayer SAM may be substantially defined as a lower surface of the nozzle part NZ.

The self-assembled monolayer SAM may include a hydrocarbon portion CH, a head portion HD coupled to an end of the hydrocarbon portion CH, and a terminal portion TA coupled to another end of the hydrocarbon portion CH. The head portion HD may be relatively hydrophilic compared to the terminal portion TA, and the head portion HD may be in contact with the lower surface of the second inorganic layer MO2. The terminal portion TA may be relatively hydrophobic compared to the head portion HD, and the terminal portion TA may be a portion in the inkjet printer head 100 (see FIG. 1A) that is the most adjacent to the target substrate SUB (see FIG. 1A). The terminal portion TA may substantially define the lowermost side of the nozzle part NZ, and the lowermost surface of the nozzle part NZ may be defined as the lowermost surface of the terminal portion TA.

The hydrocarbon portion CH may be a substituted or unsubstituted alkyl group having 1 to 60 carbon atoms. For example, the hydrocarbon portion CH may be an unsubstituted alkyl group having 8 to 60 carbon atoms. The hydrocarbon portion CH may be an unsubstituted straight-chain alkyl group having 8 to 60 carbon atoms or an unsubstituted branched-chain alkyl group having 8 to 60 carbon atoms. FIG. 3B schematically illustrates, for convenience of illustration, the hydrocarbon portion CH in the form of a straight line bent twice, but the number of carbon atoms in the hydrocarbon portion CH is not limited thereto, and the hydrocarbon portion CH may have various chemical formulas.

The head portion HD may be connected to an end of the hydrocarbon portion CH. The head portion HD may include at least one of moieties represented by Formula 1-1, Formula 1-2, and Formula 1-3 below.

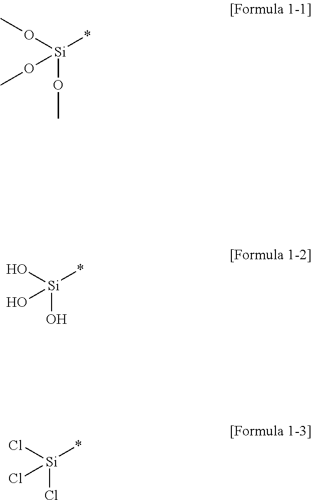

In Formula 1-1 to Formula 1-3, [symbol] may be a position connected to the end of the hydrocarbon portion CH.

The terminal portion TA may be connected to another end of the hydrocarbon portion CH. The terminal portion TA may include at least one of moieties represented by Formula 2-1, Formula 2-2, Formula 2-3, and Formula 2-4 below. As the terminal portion TA includes one of the moieties represented by Formulas 2-1 to 2-4 below, a lower surface of the self-assembled monolayer SAM may have excellent liquid-repellent properties.

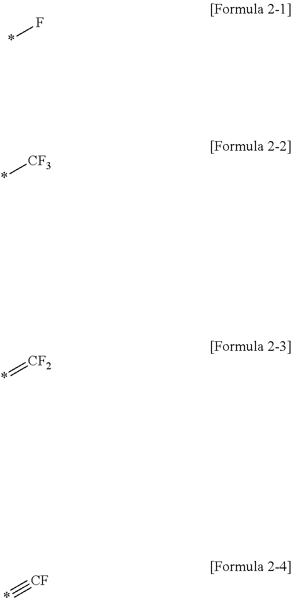

In Formula 2-1 to Formula 2-4, [symbol] may be a position connected to the another end of hydrocarbon portion.

A contact angle of the lower surface of the self-assembled monolayer SAM with respect to water may be in a range of about 90° to about 180°. Accordingly, the lower surface of the self-assembled monolayer SAM (i.e., the lower side of the nozzle part NZ) may have excellent liquid-repellent properties. As the lower surface of the nozzle part NZ has excellent liquid-repellent properties, the amount of ink adsorbed onto the nozzle part NZ may be reduced to the minimum and the ink may be discharged through the outlet port OP along a direction opposite to the third direction DR3. Accordingly, the inkjet printer device 1000 (see FIG. 1A) including the nozzle part NZ may have excellent discharge precision.

The metal oxide layer IOL may include an aluminum oxide. For example, the metal oxide layer IOL may include an aluminum oxide having a chemical formula in the form of Al_{X}O_{y} (where x and y may each be a natural number). For example, the metal oxide layer IOL may include Al₂O₃. The thickness of the metal oxide layer IOL may be in a range of about 5 nm to about 100 nm. For example, the thickness of the metal oxide layer IOL may be in a range of about 50 nm to about 80 nm. However, the disclosure is not limited thereto. The metal oxide layer IOL may be deposited in the form of a thin film by atomic layer deposition (ALD), physical vapor deposition (PVD), or sputter deposition.

The metal oxide layer IOL may include a first metal oxide portion IOL1, a second metal oxide portion IOL2 disposed on the first metal oxide portion IOL1, and a third metal oxide portion IOL3 disposed on the second metal oxide portion IOL2. The nozzle part Z may include the first metal oxide portion IOL1 and the second metal oxide portion IOL2, and the third metal oxide portion IOL3 may be included in a piezoelectric element part PZ to be described below. The first metal oxide portion IOL1, the second metal oxide portion IOL2, and the third metal oxide portion IOL3 may be formed simultaneously and integrally from a same material through a same process.

The nozzle part NZ may further include an organic layer OL disposed on the first metal oxide portion IOL1. The organic layer OL may include an organic material. The organic layer OL may include polyimide (PI). The organic layer OL may be composed of polyimide. A three-dimensional shape of the organic layer OL may substantially define a three-dimensional shape of the nozzle part NZ. The organic layer OL may substantially define the shape of the nozzle part NZ, the first metal oxide portion IOL1, the first and second inorganic layers MO1 and MO2, and the self-assembled monolayer SAM may be sequentially formed on a lower surface of the organic layer OL in a direction opposite to the third direction DR3, and the second metal oxide portion IOL2 may be disposed directly on a side surface of the organic layer OL. For example, the first and second metal oxide portions IOL1 and IOL2, the first and second inorganic layers MO1 and MO2, and the self-assembled monolayer SAM may each be attached on the external shape of the organic layer OL.

The first metal oxide portion IOL1 may be disposed on a first upper surface US of the first inorganic layer MO1. A lower surface of the first metal oxide portion IOL1 may contact the first upper surface US of the first inorganic layer MO1. An upper surface of the first metal oxide portion IOL1 may contact the lower surface of the organic layer OL. The second metal oxide portion IOL2 may contact the side surface of the organic layer OL. The second metal oxide portion IOL2 may entirely cover the side surface of the organic layer OL.

The first metal oxide portion IOL1 may be disposed on the first upper surface US of the first inorganic layer MO1, and the second inorganic layer MO2 may be disposed on the first lower surface LS of the first inorganic layer MO1. With respect to water, a contact angle of the first upper surface US may be lower than a contact angle of the first lower surface LS. The surface roughness of the first upper surface US may be lower than the surface roughness of the first lower surface LS. In an embodiment, at least a portion of the first lower surface LS of the first inorganic layer MO1 may be a plasma-treated surface. In a step of preparing the first inorganic layer MO1, at least a portion of the first lower surface LS of the first inorganic layer MO1 may be plasma-treated. For example, at least a portion of the first lower surface LS of the first inorganic layer MO1 may be plasma-treated by oxygen (O₂), argon (Ar), or atmospheric pressure during the preparation. Accordingly, compared to the first upper surface US not plasma-treated during the preparation, a contact angle of the first lower surface LS with respect to water may be relatively large, and the surface roughness of the first lower surface LS may be relatively large. Compared to the lower surface of the second inorganic layer MO2 not plasma-treated during the preparation, the contact angle of the first lower surface LS with respect to water may be relatively large, and the surface roughness of the first lower surface LS may be relatively large. For example, according to the presence or absence of a plasma treatment step in the preparation, the hydrophobicity of the first lower surface LS and the surface roughness of the first lower surface LS may be relatively large compared to that of the first upper surface US and the second inorganic layer MO2, respectively. If at least a portion of the first lower surface LS of the first inorganic layer MO1 is treated with oxygen plasma during the preparation, compared to the first upper surface US or the lower surface of the second inorganic layer MO2, the first lower surface LS may have a relatively high oxygen atomic ratio.

The piezoelectric element part PZ may include a piezoelectric element PZE, a cover layer OC which surrounds the piezoelectric element PZE, and the third metal oxide portion IOL3 which surrounds the cover layer OC. The piezoelectric element part PZ may further include an adhesive layer EP which attaches the nozzle part NZ and the piezoelectric element PZE.

The piezoelectric element PZE may control whether the ink temporarily stored in the storage part SP is discharged from the outlet port OP or the amount of the ink temporarily stored in the storage part SP discharged from the outlet port OP. A voltage applied to the piezoelectric element PZE may control the pressure applied to the ink temporarily stored in the storage part SP. Due to the pressure applied to the piezoelectric element PZE, if a pressure greater than a specific numerical value is applied to the ink temporarily stored in the storage part SP, the ink may be sprayed onto the target substrate SUB (see FIG. 1A) through the storage part SP and the outlet port OP.

The cover layer OC may include an organic material. The cover layer OC may include parylene. For example, the cover layer OC may include Parylene-C or Parylene-N. The cover layer OC may cover an entire surface of the piezoelectric element PZE, and accordingly the storage part SP defined in the piezoelectric element part PZ may be planarized. The cover layer OC may have a thickness in a range of about 0.1 μm to about 5 μm. For example, the cover layer OC may have a thickness in a range of about 2.5 μm to about 5 μm. The cover layer OC may be deposited by a chemical vapor deposition (CVD).

The third metal oxide portion IOL3 may cover the cover layer OC. A portion of the third metal oxide portion IOL3 may contact an upper surface of the organic layer OL, and another portion of the third metal oxide portion IOL3 may contact a side surface of the adhesive layer EP. The third metal oxide portion IOL3 may substantially define the outermost surface of the piezoelectric element part PZ. The storage part SP may be substantially defined by the third metal oxide portion IOL3.

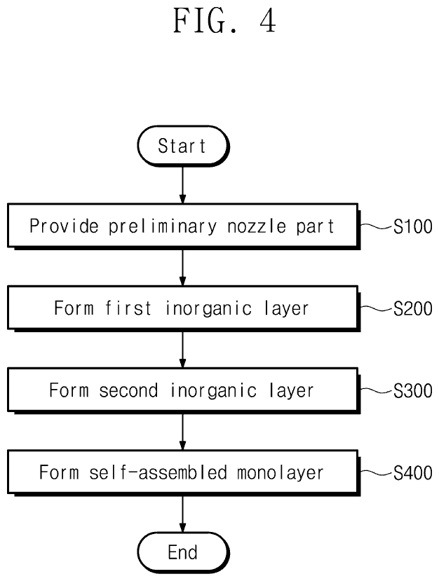

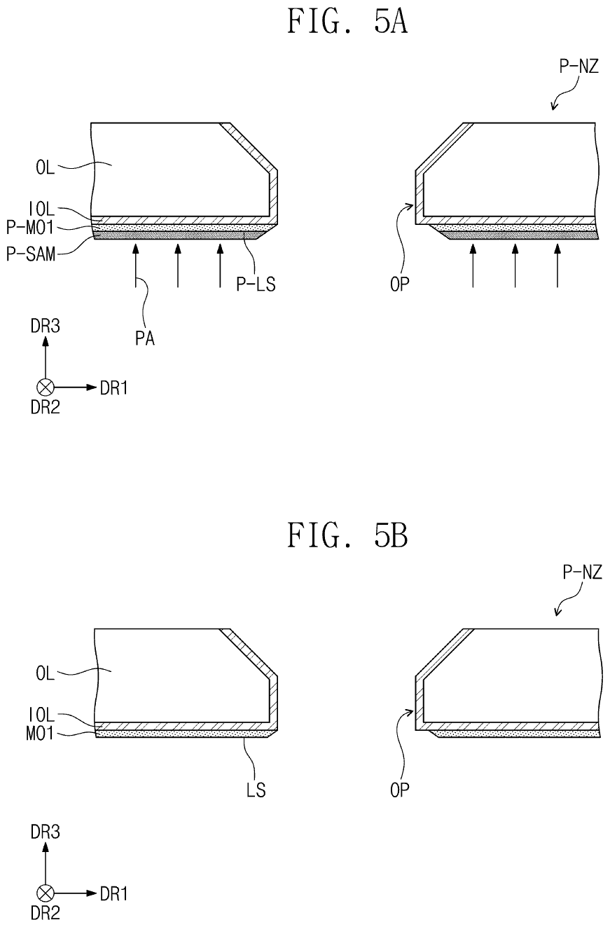

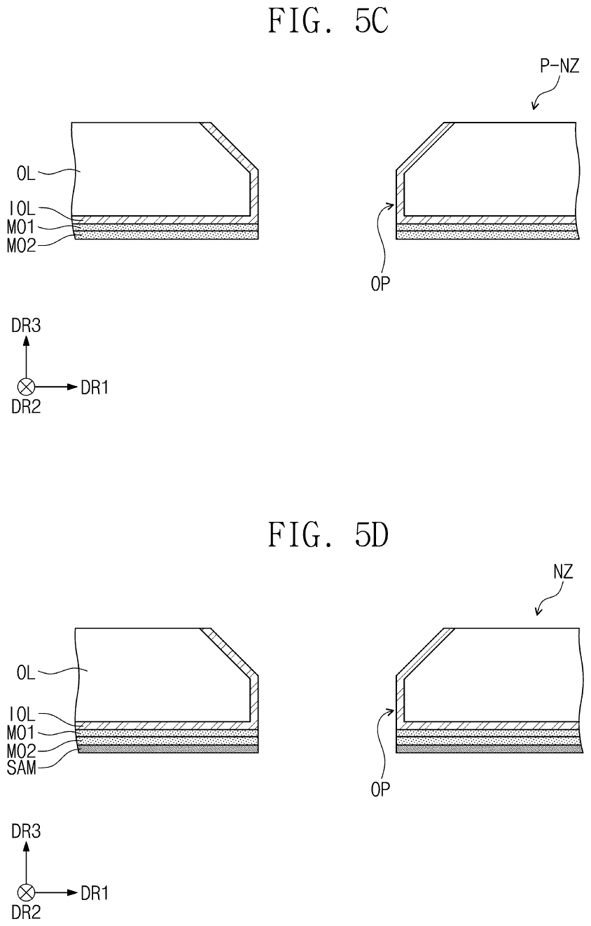

Hereinafter, a method of manufacturing an inkjet printer head according to an embodiment of the disclosure will be described with reference to FIG. 4 and FIG. 5A to FIG. 5D. In describing the method for manufacturing an inkjet printer head according to an embodiment of the disclosure, the same reference numerals are given to the same components as those described above, and detailed descriptions are omitted.

FIG. 4 is a flowchart showing some of the steps of a manufacturing method of an inkjet printer head of an embodiment of the disclosure.

Referring to FIG. 4, the manufacturing method of the inkjet printer head 100 according to an embodiment of the disclosure may include providing a preliminary nozzle part S100, forming a first inorganic layer S200, forming a second inorganic layer S300, and forming a self-assembled monolayer S400.

FIG. 5A to FIG. 5D are schematic cross-sectional views sequentially showing some of the steps of a manufacturing method of an inkjet printer head according to an embodiment of the disclosure. FIG. 5A to FIG. 5D are views sequentially showing a part of a step of forming the nozzle part NZ in the manufacturing method of the inkjet printer head 100 according to an embodiment of the disclosure.

Referring to FIG. 5A, the manufacturing method of the inkjet printer head 100 according to an embodiment of the disclosure may include providing a preliminary nozzle part P-NZ. The preliminary nozzle part P-NZ may include a metal oxide layer IOL, a preliminary first inorganic layer P-MO1 disposed on a lower surface of the metal oxide layer IOL, and a preliminary self-assembled layer P-SAM disposed on a lower surface of the preliminary first inorganic layer P-MO1.

The preliminary first inorganic layer P-MO1 may be disposed on the lower surface of the metal oxide layer IOL. The preliminary first inorganic layer P-MO1 may be disposed on a lower surface of the metal oxide layer IOL. The preliminary first inorganic layer P-MO1 and the first inorganic layer MO1 may include a same material. The preliminary first inorganic layer P-MO1 may include a silicon oxide. The preliminary first inorganic layer P-MO1 may include SiO₂.

The preliminary self-assembled layer P-SAM may be disposed on the lower surface of the preliminary first inorganic layer P-MO1. The preliminary self-assembled layer P-SAM and the self-assembled monolayer SAM may include a same material. The preliminary self-assembled layer P-SAM and each of the head portion HD (see FIG. 3B), the hydrocarbon portion CH (see FIG. 3B), and the terminal portion TA (see FIG. 3B) of the self-assembled monolayer SAM may include a same material.

The preliminary nozzle part P-NZ may be included in the inkjet printer device 1000 (see FIG. 1A) used by a user for a period of time. The preliminary nozzle part P-NZ may be at least partially aged due to the use of the user for a period of time. As ink is discharged and stored for number of times or more for a period of time, the preliminary nozzle part P-NZ may be at least partially worn. For example, each of the preliminary first inorganic layer P-MO1 and the preliminary self-assembled layer P-SAM may be relatively at least partially worn compared to each of the second inorganic layer MO2 (see FIG. 5D) and the self-assembled monolayer SAM, which will be described below.

Referring to FIG. 5A and FIG. 5B, the manufacturing method of the inkjet printer head 100 according to an embodiment of the disclosure may include forming the first inorganic layer MO1 after the providing of the preliminary nozzle part P-NZ. The step of forming the first inorganic layer MO1 may include removing the preliminary self-assembled layer P-SAM from a lower surface P-LS of the preliminary first inorganic layer P-MO1. The step of removing the preliminary self-assembled layer P-SAM may include a process of irradiating a lower portion of the preliminary self-assembled layer P-SAM with plasma PA. The lower surface P-LS of the preliminary first inorganic layer P-MO1 may be irradiated with at least a portion of the plasma PA. The plasma PA may be oxygen (O₂) plasma or argon (Ar) plasma, but the disclosure is not limited thereto. As the preliminary self-assembled layer P-SAM is plasma-treated, the lower surface P-LS of the preliminary first inorganic layer P-MO1 may be at least partially modified. Since the lower surface P-LS of the preliminary first inorganic layer P-MO1 is at least partially modified by the plasma PA, the first inorganic layer MO1 may be formed.

A contact angle of the lower surface P-LS of the preliminary first inorganic layer P-MO1 with respect to water may be different from a contact angle of the first lower surface LS of the first inorganic layer MO1. The contact angle of the lower surface P-LS of the preliminary first inorganic layer P-MO1 with respect to water may be greater than the contact angle of the first lower surface LS of the first inorganic layer MO1. For example, the hydrophobicity of the lower surface P-LS of the preliminary first inorganic layer P-MO1 may be greater than the hydrophobicity of the first lower surface LS of the first inorganic layer MO1. Since the first inorganic layer MO1 is formed through the plasma PA process, the first lower surface LS of the first inorganic layer MO1 may be more hydrophilic than the lower surface P-LS of the preliminary first inorganic layer P-MO1. The surface roughness of the lower surface P-LS of the preliminary first inorganic layer P-MO1 may be different from the surface roughness of the first lower surface LS of the first inorganic layer MO1. The surface roughness of the lower surface P-LS of the preliminary first inorganic layer P-MO1 may be lower than the surface roughness of the first lower surface LS of the first inorganic layer MO1. Since the first inorganic layer MO1 is formed through the plasma PA process, the first lower surface LS of the first inorganic layer MO1 may have greater surface roughness than the lower surface P-LS of the preliminary first inorganic layer P-MO1. If the plasma PA used in the forming of the first inorganic layer MO1 is oxygen plasma, the first lower surface LS of the first inorganic layer MO1 may have a relatively high oxygen atomic ratio compared to the lower surface P-LS of the preliminary first inorganic layer P-MO1.

Referring to FIG. 5C, the manufacturing method of the inkjet printer head 100 according to an embodiment of the disclosure may include forming the second inorganic layer MO2 after the forming of the first inorganic layer MO1. The second inorganic layer MO2 may be formed on a lower surface of the first inorganic layer MO1. The second inorganic layer MO2 may be formed by a thermal evaporation method or an electron beam evaporation method.

Referring to FIG. 5D, the manufacturing method of the inkjet printer head 100 according to an embodiment of the disclosure may include forming the self-assembled monolayer SAM after the forming of the second inorganic layer MO2. The self-assembled monolayer SAM may be formed on a lower surface of the second inorganic layer MO2.

The method for manufacturing an inkjet printer head according to an embodiment of the disclosure may include removing a preliminary self-assembled layer P-SAM, forming a second inorganic layer MO2, and forming a self-assembled monolayer SAM. A nozzle part NZ manufactured by the method for manufacturing an inkjet printer head according to an embodiment of the disclosure may have relatively excellent liquid-repellent properties compared to an aged preliminary nozzle part, so that ink discharge precision and discharge capacity may be improved. Accordingly, according to the method for manufacturing an inkjet printer head according to an embodiment of the disclosure, an aged preliminary nozzle part may be reused as a nozzle part NZ, so that the process efficiency of a user who uses an inkjet printer may increase. An inkjet printer device according to an embodiment of the disclosure may include a nozzle part NZ which includes first inorganic layer MO1, a metal oxide layer IOL, and a self-assembled monolayer SAM. Accordingly, the inkjet printer device according to an embodiment of the disclosure may have improved precision of ink discharge. In the inkjet printer device according to an embodiment of the disclosure, a lower surface of a first inorganic layer MO1 may be at least partially plasma-treated, and thus, may have a relatively low contact angle. Accordingly, the inkjet printer device according to an embodiment of the disclosure may implement an advantageous reuse effect.

An inkjet printer device of an embodiment may have excellent discharge efficiency and wear resistance properties at the same time since a nozzle part NZ includes a first inorganic layer MO1, a metal oxide layer IOL, and a self-assembled monolayer SAM, wherein a lower surface of the first inorganic layer MO1 has constant properties.

A method for manufacturing an inkjet printer head of an embodiment may manufacture an inkjet printer head with improved reusability by including the steps of forming a first inorganic layer, forming a second inorganic layer, and the like.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An inkjet printer device comprising:
a stage; and
an inkjet printer head disposed on the stage, wherein
the inkjet printer head includes:
a chamber part for providing ink; and
a nozzle part which is disposed under the chamber part and in which a plurality of outlet ports for discharging the ink are defined,
the nozzle part includes:
a first inorganic layer;
a metal oxide layer disposed on a first upper surface of the first inorganic layer;
a second inorganic layer disposed on a first lower surface of the first inorganic layer; and
a self-assembled monolayer disposed on a lower surface of the second inorganic layer,
a contact angle of the first lower surface with respect to water is lower than a contact angle of the first upper surface with respect to water, and
the first inorganic layer and the second inorganic layer include a same material.

2. The inkjet printer device of claim 1, wherein a surface roughness of the first lower surface is higher than a surface roughness of the first upper surface.

3. The inkjet printer device of claim 1, wherein the contact angle of the first lower surface with respect to water is lower than a contact angle of the lower surface of the second inorganic layer with respect to water.

4. The inkjet printer device of claim 1, wherein
a thickness of the second inorganic layer is in a range of about 1 nm to about 50 nm, and
a thickness of the first inorganic layer is less than the thickness of the second inorganic layer.

5. The inkjet printer device of claim 1, wherein
the metal oxide layer comprises aluminum oxide, and
the first inorganic layer and the second inorganic layer each comprises a silicon oxide.

6. The inkjet printer device of claim 5, wherein an atomic ratio of oxygen (O) atom included in the first lower surface is higher than an atomic ratio of oxygen (O) atom included in the first upper surface.

7. The inkjet printer device of claim 1, wherein the second inorganic layer and the self-assembled monolayer do not overlap the plurality of outlet ports defined in the nozzle part in a plan view.

8. The inkjet printer device of claim 1, wherein a contact angle of a lower surface of the self-assembled monolayer with respect to water is in a range of about 90° to about 180°.

9. The inkjet printer device of claim 1, wherein
the self-assembled monolayer includes a hydrocarbon portion, a head portion connected to an end of the hydrocarbon portion, and a terminal portion connected to another end of the hydrocarbon portion, and
the head portion is in contact with the lower surface of the second inorganic layer.

10. The inkjet printer device of claim 9, wherein the head portion comprises one of moieties represented by Formula 1-1, Formula 1-2, and Formula 1-3 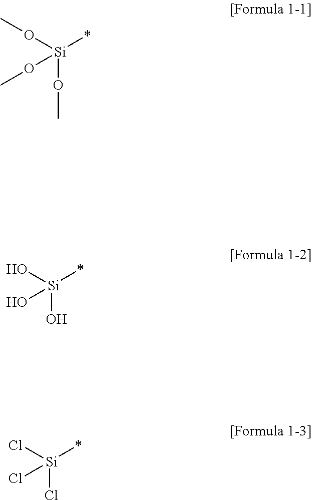
wherein in Formula 1-1 to Formula 1-3, [symbol] is a position connected to the end of the hydrocarbon portion.

11. The inkjet printer device of claim 9, wherein the terminal portion comprises one of moieties represented by Formula 2-1, Formula 2-2, Formula 2-3, and Formula 2-4 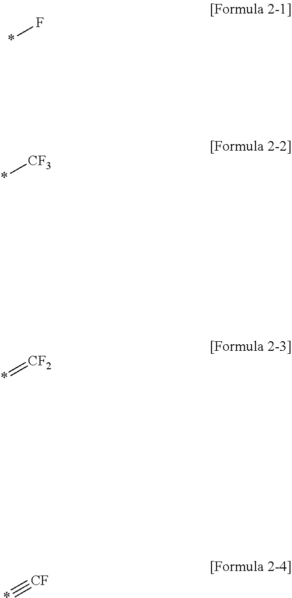
wherein in Formula 2-1 to Formula 2-4, [symbol] is a position connected to the another end of the hydrocarbon portion.

12. The inkjet printer device of claim 9, wherein the hydrocarbon portion is an unsubstituted alkyl group having 8 to 60 carbon atoms.

13. The inkjet printer device of claim 1, wherein the inkjet printer head further includes a piezoelectric element part disposed between the chamber part and the nozzle part and applying pressure to the ink.

14. The inkjet printer device of claim 13, wherein the nozzle part further includes an organic layer disposed between the piezoelectric element part and the first inorganic layer.

15. The inkjet printer device of claim 14, wherein the organic layer comprises polyimide (PI).

16. A method for manufacturing an inkjet printer head including a chamber part for providing ink, a piezoelectric element part disposed under the chamber part and applying pressure to the ink, and a nozzle part disposed under the piezoelectric element part and having a plurality of outlet ports, the method comprising:
forming the nozzle part, wherein the forming of the nozzle part includes:
providing a preliminary nozzle part including a metal oxide layer, a preliminary first inorganic layer disposed on a lower surface of the metal oxide layer, and a preliminary self-assembled layer disposed on a lower surface of the preliminary first inorganic layer;
forming a first inorganic layer by irradiating the preliminary self-assembled layer with plasma to remove the preliminary self-assembled layer from the lower surface of the preliminary first inorganic layer;
forming a second inorganic layer on a lower surface of the first inorganic layer; and
forming a self-assembled monolayer on a lower surface of the second inorganic layer.

17. The method of claim 16, wherein in the forming of the first inorganic layer,
the plasma is irradiated from the lower surface of the preliminary self-assembled layer, and
the plasma is irradiated onto at least a portion of the lower surface of the preliminary first inorganic layer.

18. The method of claim 16, wherein the forming of the second inorganic layer is performed by a thermal deposition process or an electron beam deposition process.

19. The method of claim 16, wherein the preliminary first inorganic layer, the first inorganic layer, and the second inorganic layer each comprises a silicon oxide.

20. The method of claim 16, wherein the preliminary self-assembled layer and the self-assembled monolayer include a same material.
